(19) United States
(12) Patent Application Publication
(10) Pub. No.: US 2007/0281081 A1
(43) Pub. Date: Dec. 6, 2007

(54) Vacuum Deposition Method and Sealed-Type Evaporation Source Apparatus for Vacuum Deposition

(76) Inventors: Hiroki Nakamura, Chiba (JP); Toshinori Takagi, Kyoto (JP)

Correspondence Address: Quarles & Brady, 411 E. Wisconsin Avenue, Milwaukee, WI, 53202, US

(21) Appl. No.: 10/586,400

(22) PCT Filed: Jan. 21, 2005
(86) PCT No.: PCT/JP05/01174

§ 371 Date: Apr. 20, 2007

(30) Foreign Application Priority Data
Jan. 22, 2004 (JP) 2004-014341

(51) Int. Cl. C23C 14/24

(52) U.S. Cl. 427/248.1; 118/726

(57) ABSTRACT

A vacuum deposition method is provided. In the vacuum deposition for evaporating a sublimation evaporation material, the gas sealed-type heating container 11 has the blast aperture 14 and an area for evaporating the evaporation material by the radiation heat from the inner surface thereof. The holder 15 holds an evaporation material in a region in which the evaporation material does not evaluate due to the heat transferred from the heating container 11. Thus, the generated vapor is emitted from the blast aperture 14 into the deposition subject surface outside the container.

### TECHNICAL FIELD

The present invention relates to a vacuum deposition method and a sealed-type evaporation source apparatus for vacuum deposition of a sublimation material, which uses a sealed heating container having an evaporation material blast aperture. More particularly, the present invention relates to a vacuum deposition method that utilizes the system of emitting and evaporating an evaporation material by utilizing a large pressure difference between a deposition chamber and a heating container. Moreover, the present invention relates to a sealed-type evaporation source apparatus for vacuum deposition. In explanation, the evaporation material, the heating container, and the related components are comprehensively referred to as “sealed evaporation source”.

### BACKGROUND OF THE INVENTION

Conventionally, an open type evaporation source, where the pressure difference between an evaporation chamber and a heating chamber is not utilized, has been broadly used as a evaporation source for vacuum deposition. Meanwhile, it is very difficult to find the case where an evaporation source called a sealed-type evaporation source where an evaporation material is blasted and evaporated under a large pressure difference is in a practical use.

There are two methods for vaporizing solids. That is, one method is to electrically heat a container in which a solid to be evaporated is held or placed is electrically heated. The other method is to directly irradiate electron beams onto a solid. These methods are generally called open-type evaporation sources. However, either method is different from the method of storing evaporated gases in a space with a volume sectioned from the vacuum chamber on the deposition side and blasting as a jet it under the resultant pressure. In the case of the open-type evaporation source, the translational motion velocity of evaporated gases travelling from an evaporation source to a deposition subject surface (hereinafter merely referred to as “substrate”) outside the container is defined by the velocity of the free motion of each of molecules determined by a heating temperature for evaporation and is equalized to the sonic speed under conditions in the spot.

On the other hand, in the case of a sealed-type evaporation source, an evaporation source that heats a container holding a solid or a container in which a solid is placed is used and vaporizes the solid. The pressure in the container is set to a large value by far than the pressure in the vacuum chamber on the deposition side. Thus, a jet of gas is obtained from a small aperture. In this case, the translational motion velocity becomes a supersonic velocity because it is accelerated by the resultant blast velocity increment.

In the case of the open-type evaporation source, if the substrate is in level and an arbitrary point of an evaporation area is set as a center axis, the distribution in thickness of the film deposited on the substrate indicates a smooth convex circular surface according to a change in the radiation angle. In the case of the sealed-type evaporation source, it is assumed that the substrate is in level when each of the apertures has a given shape, a small open area, and a certain passage distance. In the distribution in thickness of a film deposited on the substrate, the vapor acting as a gas viscous flow indicates a relatively sharp convex circular surface according to a change in the radiation angle with respect to a specific point in the open aperture acting as a center axis (in actual, the projection shape is relevant to the wall surface resistance of an aperture and diffuses to a large resistance side).

The velocity of a molecular motion affects the quality of a deposition film. However, in comparison between the open-type evaporation source that provides a translational motion velocity equal to the sonic speed and the sealed-type evaporation source that provides a translational motion velocity of the supersonic speed, the sealed-type evaporation source can provide a good film quality even if the velocity is high only in the blast direction. Moreover, the sealed evaporation source provides a film having a sharp convex surface. That is, the ejection of the evaporation material to the substrate with a narrow directivity means that a thick film formation rate in a fixed area is fast. Moreover, by irradiating electrons onto a molecular cluster created in the adiabatic expansion process of an ejected (or blast) vapor to form an ionized cluster and accelerating the ionized cluster in the electric field, the film quality can be improved. This is well known as the “Ionized Cluster Beam Method”. The properties of the sealed-type evaporation source, such as the supersonic property, directivity, cluster formation property of an ejected vapor, should be utilized more. However, those properties can be often observed in experiments but the practical examples are scarcely observed. It is considered that the reason is as follows:
(1) In the previous sealed-type evaporation source, because the internal pressure increases, the evaporation material itself sputters at a high speed from the blast aperture, with a jet of the evaporated gas. This merely leads to a loss of the material and the sputtering material hitting the substrate damages the quality of a deposition film. In other words, the high internal pressure to obtain supersonic translation velocity causes a high-speed material sputtering phenomenon.
(2) Since the vapor, not be ejected, is re-solidified inside the evaporation source under the pressure of the sealed evaporation source, the open-type evaporation source with no pressure can provide a larger amount of evaporation if the same temperature condition and the same evaporable surface area are given.
(3) In the sealed-type evaporation source, it is difficult to hold and place an evaporation material in the inside thereof through the small blast aperture in the preparation step. For that reason, it is necessary that after the evaporation source is opened, the evaporation material is inserted and sealed. This process requires the steps of disassembling the heating mechanism portion, in addition to the container for an evaporation source, and removing the material sputtering prevention barrier (to be explained later) mounted on the inside. Accordingly, the sealed-type evaporation source cannot be easily handled, compared with the open-type evaporation source.
(4) In the sealed-type evaporation source, it is more difficult to refill the evaporation material during evaporation. In contrast, because the open-type evaporation source has a sufficient space, the evaporation material can be often supplied continuously.

In succession, the above-mentioned problems will be explained here in more detail. First, as to the material sputtering in the item (1), there is an important common point in the prior art where the vapor is obtained by heating the container itself, regardless of the open-type and the sealed type. The common point means undergoing the step in which the evaporation material evaporates by the conduction heat. In this case, the type of an evaporation material to be held or placed is not related to the material evaporating through the heat fusion or the sublimation material. Next, the process of evaporating and sputtering the material by a conductive heat will be studied.

FIG. 11 shows an example of a conventional typical open-type evaluation source. Also reference should be made to FIG. 2.75(a) and the article regarding “Externally Heated Crucible” shown on pages 99 and 100 of “Thin-Film Handbook” edited by Thin-film 131 committee in Japan Society for the Promotion of Science.

FIG. 12 shows an example of a conventional sealed-type evaporation source. Further reference should be made to Japanese Patent Publication No. 2710670 (particularly, refer to FIG. 4 shown as a conventional art. In this case, it is considered that the heater (not shown) bombards the side surface of a heating container with electrons).

In the externally heated crucible 100 being a conventional open-type evaporation source, shown in FIG. 11, an alumina-cement made inner crucible 102 (in this case, corresponding to a heating container), is disposed inside an external crucible 101 provided with a thermal shield. The inner crucible 102 has an open top, a bottom, and a wall around which a heating tungsten coil 103 is wound. An evaporation material (not shown in FIG. 11), placed in the heating container 102 is evaporated by electrically heating the tungsten coil 103.

In other words, in the heating container 102, or an open-type evaporation source, the evaporation material is not shown. The heat from the wall of the heating container 102 is transferred to the bottom surface thereof. Meanwhile, the heat shield crucible 101 disposed around the container prevents the generated heat from being lost externally as degree as possible. Hence, it is well understood that the evaporation material in direct contact with the inner surface of the evaporation source evaporates by the conduction heat.

Referring to FIG. 12, the evaporation generation crucible 110 being a conventional sealed-type evaporation source has the crucible 111 with a bottom (in this case, corresponding to a heating crucible). The heating container 111 is filled with a desired amount of evaporation materials 114. The top of crucible 111 is closed detachably with a lid plate 112 having a nozzle 113 in the center thereof.

Accordingly, in the heating container 111, or the sealed-type evaporation source, since the evaporation material 114 is in direct contact with the heating portion, except the upper space, the evaporation material is vaporized due to the conduction heat.

Generally, the space in which vapor can exist is required to evaporate a solidified material (solid, liquid). In explanation of an example of an open-type evaporation source shown in FIG. 11, the upper space that does not have a pressure boundary to a vacuum chamber is a vapor existence area. In the case of the evaporation source apparatus, the heat received by an evaporation material provides a highest temperature on the contact surface to the heating container 102 and provides a decreased temperature as the evaporation material is separated away from the contact surface. In the contact surface area, because there is no space itself in which vapor exists even when the heating temperature is at the evaporation temperature of an evaporation material, the solidified material (an evaporation material) does not evaporate while the temperature gradually increases (leads to sensible heat). Meanwhile, the heat is given to the evaporation material at the portion away from the contact surface area. After a lapse of time, the temperature of a surface area of an evaporation material interfacing with a space reaches a vaporization temperature, so that the evaporation phenomenon occurs.

In that case, in the material changing in phase from solid to liquid, the heat of the whole container tends to uniformalize because the convection motion exists inside the heating container 102. However, in the case of sublimation materials, because the convection does not occur, it is hard to uniformalize the heat distribution. In any case, when the temperature is added excessively or the rise time of temperature is decreased, the evaporation material in direct contact with the heating area of the heating container 102, or a heating element, exceeds the limit of the sensible heat and vaporizes for the space. As a result, sputtering of an evaporation material occurs.

In many cases, the sublimation materials are used in the form of powdered grain, which easily travel along the shape of the inside of the heating container being an evaporation source. Therefore, the evaporation material sputters violently. That is, the evaporation material sputter phenomenon of that type is called “splash” or “spit”, thus decreasing the process yield of the evaporation material. Moreover, the splash bombarding the substrate deposition surface damages the film surface and leads to an unstable evaporation amount.

In contrast, because the internal pressure does not occur in the open-type evaporation source, the sputtering of the material can be suppressed under control of temperature and under control of temperature rise time. However, in the sealed-type evaporation source in which the internal pressure exists, the sputtering of the material cannot be sufficiently prevented under temperature control and under control of temperature rise time. That is, in the case of the sealed-type evaporation source as shown in FIG. 12, because the material is blasted together with the vapor, the ejection velocity is significant, in comparison with that in the open-type evaporation source. As a result, the blast material reaching the substrate degrades the film quality.

In order overcome such problems, the sealed-type evaporation source utilizes a barrier acting as means for preventing an evaporation material from being sputtered. FIG. 13 shows an example of a sputtering prevention barrier built in the inside of the heating container of the evaporation source.

In other words, in the crucible 120, shown in FIG. 13, a heating container 121 includes an upper heating cylinder 122 and the lower cylinder 125, which are separable from each other. The upper heating cylinder 122 has an upper electrode 123 and a blast aperture or nozzle 124 formed in the center thereof. The lower heating cylinder 125 has a lower electrode 126 and contains a sublimation evaporation material 129 on the bottom thereof. By using the separate surface, the upper barrier plate 127 and the lower barrier plate 128 are assembled detachably and at a predetermined interval. The upper barrier plate 127 has a through hole 127a and the lower barrier plate 128 has a through hole 128a. The through holes 127a and 128a are shifted from each other in an opposed position relationship. The heating container 121 itself is resistance-heated by electrically energizing through the electrodes 123 and 126.

In the case of the heating container 121 having the above-mentioned configuration, the vapor, which generates from the surface of the heated evaporation material 129, moves radically. However, since the through holes 127a in the barrier plate 127 and the through hole 128a in the barrier plate 128 are staggered, the vapor cannot pass through straightly. The vapor strikes against the barrier plates 127, 128, thus moving randomly. That is, such movement suppresses the sputtering of the material.

However, in the case of the sealed-type evaporation source, the barrier structure is inevitably complicated to suppress completely the sputtering of the material so that the space through which vapor passes is narrowed. As a result, the vapor re-solidification ratio becomes large but the blast amount decreases. Hence, because the deposition rate becomes small, a good evaporation source cannot be realized practically.

In the previous sealed-type evaporation source, even if the intake capacity of an evaporation material is increased to provide deposition over a long time or to obtain a high evaporation rate, the sputtering amount of the evaporation material increases proportionally. Hence, it was required to limit type of evaporation material, intake capacity, heating temperature, evaporation time, and the like. This is one reason why the use of the sealed evaporation source is restricted to an experimental stage and it makes difficult to bring the sealed evaporation source into a wide practical use.

Next, as to the evaporation amount in the item (2), when the interface area to the space is set to the same value under the same temperature condition, the open-type evaporation source naturally has a larger evaporation amount per time than that in the sealed-type evaporation source. In the open-type evaporation source, all the vapors translate into the vacuum space at a sonic speed determined by the conditions of the field. On the other hand, in the sealed-type evaporation source, a fixed amount of vapor from the interface area re-deposits onto the surface of materials not vaporized and then converts to a solid state. The vapor is blasted from the aperture only under a fixed dynamic equilibrium condition at a supersonic speed.

As to the item (3), in the open-type evaporation source, the evaporation material can be supplied in the unchanged aspect, as easily understood from FIG. 11. However, in the sealed evaporation source, it is difficult to supply the evaporation material 114 if the cover plate 112 having the blast aperture 113 is not once removed or the divided portions formed in the body of the heating container 111 are not disassembled. In that case, since a heating mechanism is inevitably built in the evaporation source, the heating mechanism has to be disassembled. Moreover, the barrier plate built in the container, as shown in FIG. 13, has to be disassembled. Accordingly, the open-type evaporation source has the advantage obviously in the handling.

Finally, as to the item (4), in the sealed-type evaporation source, because even the set-up stage includes a disassembly operation, it is impossible to supply the evaporation material during evaporation, as described in the item (3). Even if the evaporation material could be supplied from the blast aperture, the blast or fixed blast of vapor becomes impossible. In the open-type evaporation source, it is known that there is the case where an evaporation material is supplied during evaporation by utilizing a wide open space.

As to the items (1) to (4), the problems and actual conditions of the sealed-type evaporation source have been explained in comparison with the open-type evaporation source. However, if the items (1) to (4) are not improved, particularly, if the item (1) is not solved, it is difficult to fully use the sealed-type evaporation source even if the supersonic translation velocity or other effect of the vapor is known.

Previously, it has been briefly described that the translation velocity in evaporation is related to the quality of a deposition film. Here, the translation velocity depends on a molecular motion velocity. The molecular motion velocity depends on temperatures. However, even at the same temperatures, the sealed-type evaporation source differs largely from the open-type evaporation source in the translation velocity. Next, the translation velocities will be compared in the case when water vapor, of which the ratio of specific heat is known, is shown as an example.

That is, the free motion velocity of water molecules at 100° C. is 415 m/sec. This is transformed into a translation velocity (sound speed) of 300 m/sec. When it is assumed that the pressure in the vacuum chamber in the sealed-type evaporation source is 8 ×10⁻³ Pa, and the pressure in the evaporation source at 100° C. is 133 Pa, a translation velocity of 1179 m/sec can be obtained from the blast aperture. That is, the translation velocity about four times that of the water vapor can be obtained at the same temperature. Therefore, the energy determining the quality of a deposition film is large by the corresponding value.

The example of the water vapor is applicable to other molecules with different numeric values. In this case, improving the quality of a deposition film does not depend on only the high motion velocity of molecules. However, the molecular motion velocity is one of the most important factors. In the present circumstances, it is considered that only the sealed-type evaporation source can increase the motion velocities of respective molecules with the capability of the evaporation source itself.

However, since the sealed evaporation source cannot be now utilized broadly because of the previously described reasons, the open-type evaporation source has been used to improve the quality of a deposition film. For example, a combination of the open-type evaporation source and an argon ion assist or deposition due to sputtering can obtain deposition films of a relatively good quality under the open condition. Either approach contributes to improving the effect of ions and the molecular motion velocities. However, even if deposition films of good quality can be obtained through either approach, the argon ion assist method requires an expensive argon ion unit. The sputtering apparatus is costly and the target cost is expensive. The sputtering apparatus does not have a high productivity.

As described previously, the sealed-type evaporation source has unavoidably the problems described in the items (1) to (4). However, according to the present invention, if the items (1) to (4) can be solved as to the evaporation of a sublimation material, the quality of a deposition film equal to the film quality formed through the argon ion assist or sputtering can be obtained. In the breakthrough, it is possible to realize a good quality of a deposition film, a high productivity and a low production cost and to facilitate putting the “Ionized Cluster Beam” technique to a practical use.

Generally, the heating container of an evaporation source inevitably has an active heating area and a passive heating area. For example, in the container utilizing the resistance heating, the energizing area corresponds to an active heating area and the other area corresponds to a passive heating area, which is chiefly heated through the conduction from the active heating area. For that reason, the temperature of the active heating area is always higher than the temperature of the passive heating area. Basically, the evaporation depends on the temperature of the active heating area. Such sorting of heating areas are certainly seen in not only the resistance heating but also in other heating means. For example, in an electron bombardment, the area to be bombarded is an active heating area and the remaining areas correspond to a passive heating area.

As described previously, evaporation by conduction heat tends to easily sputter the evaporation material because there is substantially no space for the generated vapor even when an evaporation material contact surface reaches an evaporation temperature. Particularly, in the sealed evaporation source, the evaporation material sputters at a higher velocity because of the high internal pressure.

For that reason, the evaporation material is evaporated with the radiation heat, instead of the conduction heat, or is held at the position where being not short of the evaporation temperature in the passive heating area spaced away from the active heating area of the heating container. In the event, because the surface of the evaporation material acts as an interface to the space and the vaporization phenomenon occurs in only such a area, the sputtering of the evaporation material does not occur theoretically. Moreover, because the evaporation phenomenon means a latent heat state in a layer of unvaporized evaporation material, the temperature of the evaporation material in a hold state does not increase.

In the gravitational space, it is fact in any case that all “things”, except gas, can be held, placed and fixed on the ground, in the wide sense. The fact will be explained with the relationship between a deposition apparatus and an evaporation source or between an evaporation material and a heating container constituting an evaporation source. The evaporation source is securely mounted to the deposition apparatus. The evaporation material is held or placed in the heating container. When the mutual relationship is viewed from the viewpoint of the heating area in the heating container, it is absolutely rational to decide the passive heating area of the heating container as a position fixed to the deposition apparatus. Moreover, the evaporation material can be absolutely held or placed in a stable state in the passive heating area of the heating container.

That is, the evaporation source with the above-mentioned configuration prevents a change in phase of an evaporation material. That is, the sublimation material is independent from the changing from solid to vapor and the static stability can be maintained. In other words, the means for preventing the material from sputtering can be found from the above-mentioned idea.

Even if the active heating area is heated to a sufficient evaporable temperature, the passive heating area can be maintained relatively easily below the evaporation temperature. The reason is that the fixing structure can sink the generated heat toward other area by conduction and a heat sink can be provided at that area. Thus, the evaporation material can be held or maintained in the passive heating area in a stable state and continuously.

As to the previous evaporation sources, evaporation by conduction heat was tried, but various design ideas has been made to the evaporation source to maintain the area to an evaporation temperature. By doing so, the temperature of the whole of an evaporation material can be increased rapidly and equally. As a result, the evaporation efficiency can be improved highly. However, if the sublimation evaporation material to be evaporated by radiation heat is held in a stable state, it is preferable that the holding position is away from the active heating area providing the evaporation temperature and is in the passive heating area which is not at an evaporation temperature. That is, if the holding position is at an evaporation temperature, it is impossible to hold the evaporation material in stable state.

### SUMMARY OF THE INVENTION

The present invention is made to solve the problems described in the above-mentioned items.

An object of the invention is to provide a technique of capable of effectively putting a sealed-type evaporation source into practical use in a sublimation material area.

In an aspect of the present invention, a vacuum deposition method for evaporating a sublimation or evaporation material comprises the steps of preparing a gas sealed-type heating container having a blast aperture, holding the evaporation material in the area where the evaporation material does not evaporate due to the conduction heat from the gas sealed heating container, evaporating the evaporation material held in the area by the radiation heat from the heating container, and emitting a resultant vapor from the blast aperture toward an evaporation subject surface or substrate outside the heating container.

In the vacuum deposition method according to the present invention, the heating container has a supply aperture in the area where the evaporation material does not evaporate due to the conduction heat from the heating container. The evaporation material supplied from the supply aperture is held in the area where the evaporation material does not evaporate due to the conduction heat from the heating container. The evaporation material to be supplied and held is held in the evaporation area subject to the radiation heat, so as to face in a contact-less state to the heating surface at the evaporable temperature in the heating container.

The evaporation material is in a powdered grain state and is supplied from a supply aperture formed in the heating container. The evaporation material to be supplied is held in an evaporation area subject to the radiation heat, so as to face in a contactless state to the heating surface at an evaporable temperature in the heating container.

The vapor of the evaporation material produced due to the radiation heat from the heating surface of the heating container performs a thermal disturbance motion in a space within the heating container while the part of the vapor is re-solidified onto the surface of the evaporation material, thus being maintained to a solid phase in a predetermined state.

The evaporation material is a molded compact and is supplied from a supply aperture formed in the heating container while an evaporation material to be supplied is held in an evaporation area subject to the radiation heat so as to face in a contact-less state the heating surface in the heating container, which is at the evaporable temperature.

The gas sealing property of the supply aperture formed in the heat container is maintained by the powdered grain evaporation material or the molded compact evaporation material, supplied via the supply aperture.

The gas sealing property of the supply aperture formed in the heat container is maintained by the solid state phase of the vapor partially re-solidified.

The powdered grain evaporation material is supplied into the heating container through the supply aperture in accordance with the decrease of the evaporation material because of the emission of the gas.

In another aspect of the present invention, a sealed-type evaporation source apparatus for vacuum deposition for vaporizing a sublimation evaporation material, comprises a gas sealed heating container having a blast aperture and having an area vaporizing the evaporation material with the radiation heat from an inner surface thereof, and a holder for holding the evaporation material in an area where the evaporation material does not evaporate with the conduction heat from the heating container, whereby the blast aperture emits the generated vapor toward an evaporation subject surface outside the container.

In the sealed-type evaporation source apparatus for vacuum deposition according to the present invention, the heating container has a supply aperture for evaporation material in an area where the evaporation material does not evaporate by the conduction heat from the heating container. The evaporation material to be supplied from the supply aperture is held in an area where the evaporation material does not evaporate by the conduction heat from the heating container. The evaporation material to be supplied and held is held in an evaporation area subject to the radiation heat, so as to face in a contactless state to the heating surface at the evaporable temperature in the heating container.

The evaporation material is in a powdered grain state and is supplied from a supply aperture formed in the heating container. The evaporation material to be supplied is held in an area subject to the radioactive heat, so as to face in a contactless state to the heating surface at the evaporable temperature in the heating container.

The evaporation material is a molded compact and is supplied from a supply aperture formed in the heating container. The evaporation material is held in the evaporation area subject to the radiation heat so as to face in a contactless state to the heating surface of the heating container, which is at the evaporable temperature.

The evaporation material supply aperture and the holder are disposed in the position where the evaporation material does not evaporate due to the conduction heat from said heating container.

The gas sealing property of the supply aperture formed in the heat container is maintained due to the powdered grain evaporation material or the molded compact evaporation material, supplied via the supply aperture.

The gas sealing property of the supply aperture formed in the heat container is maintained by a solid state phase of the vapor partially re-solidified.

The powdered grain evaporation material is supplied in the heating container through the supply aperture in accordance with the decrease of the evaporation material, because of the emission of the gas.

In the vacuum deposition method and the sealed-type evaporation material source apparatus for vapor deposition of the present invention, a sealed-type evaporation source can be adopted in the vacuum deposition technique using sublimation evaporation materials. Thus, the deposited thin film and the productivity thereof can be improved remarkably. Compared with the open-type evaporation source, the sealed-type evaporation source can accelerate the translational motion velocity of vapor and can largely contribute to improving the quality of a deposited thin film, thus practically demonstrating various very good features.

### BRIEF DESCRIPTION OF THE DRAWINGS

This and other objects, features, and advantages of the present invention will become more apparent upon a reading of the following detailed description and drawings, in which:

FIG. 1 is a longitudinal sectional side view conceptually illustrating the schematic configuration of a sealed-type evaporation source apparatus for vacuum deposition according to the first embodiment of the present invention;

FIG. 2 is a plan view, viewed from above, conceptually illustrating a sealed-type evaporation source apparatus according to the first embodiment of the present invention;

FIG. 3 is a longitudinal sectional side view conceptually illustrating a modification of a sealed-type evaporation source apparatus according to the first embodiment of the present invention;

FIG. 4 is a plan view, viewed from above, conceptually illustrating a modification of a sealed-type evaporation source apparatus according to the first embodiment of the present invention;

FIG. 5 is a longitudinal sectional side view conceptually illustrating the schematic configuration of a sealed-type evaporation source apparatus for vacuum deposition according to the second embodiment of the present invention;

FIG. 6 is a longitudinal sectional side view conceptually illustrating an aspect of an evaporation material after a lapse of time of the operation of a sealed-type evaporation source apparatus shown in FIG. 5;

FIG. 7 is a cross-sectional side view conceptually illustrating the region taken along the line 7-7 shown in FIG. 6;

FIG. 8 is a longitudinal sectional side view conceptually illustrating a schematic configuration of a sealed-type evaporation source apparatus for vacuum deposition according to the third embodiment of the present invention;

FIG. 9 is a longitudinal sectional side view conceptually illustrating a modification of a sealed evaporation source apparatus according to the third embodiment of the present invention;

FIG. 10 is a longitudinal sectional side view conceptually illustrating a schematic configuration of a sealed-type evaporation source apparatus for vacuum deposition according to the fourth embodiment of the present invention;

FIG. 11 is an explanatory diagram, in cross section, illustrating a conventional open-type evaporation source apparatus for vacuum deposition;

FIG. 12 is an explanatory diagram, in cross section, illustrating a conventional sealed-type evaporation source apparatus for vacuum deposition; and

FIG. 13 is an explanatory diagram, in cross section, illustrating a conventional sealed-type evaporation source apparatus with a vacuum deposition barrier.

### DESCRIPTION OF THE PREFERRED EMBODIMENTS

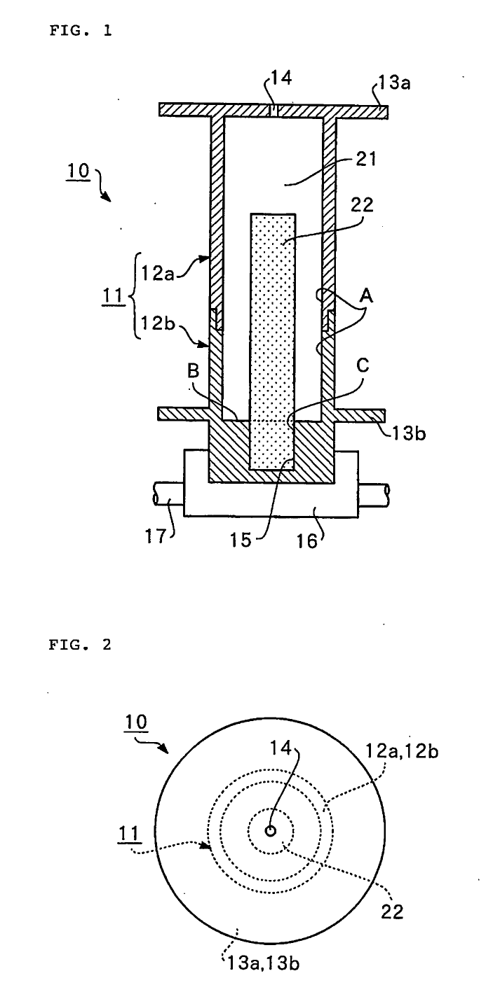

A vacuum deposition method and a sealed-type evaporation source apparatus for vacuum deposition according to the first to fourth embodiments of the present invention will be explained below by referring to FIGS. 1 to 10.

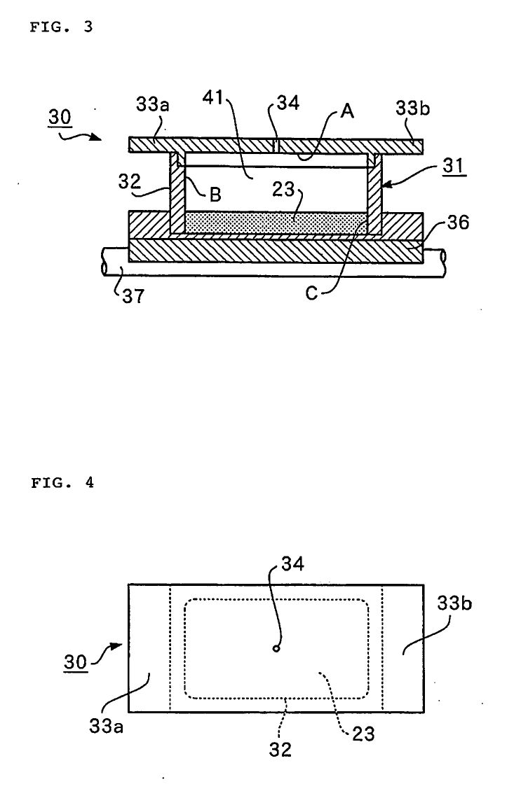

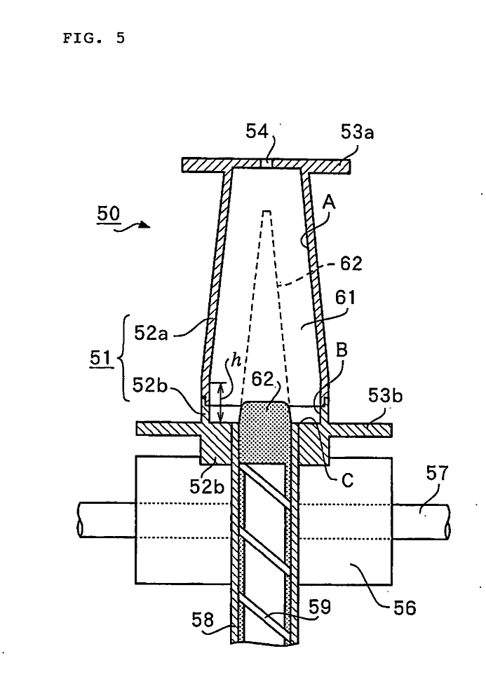

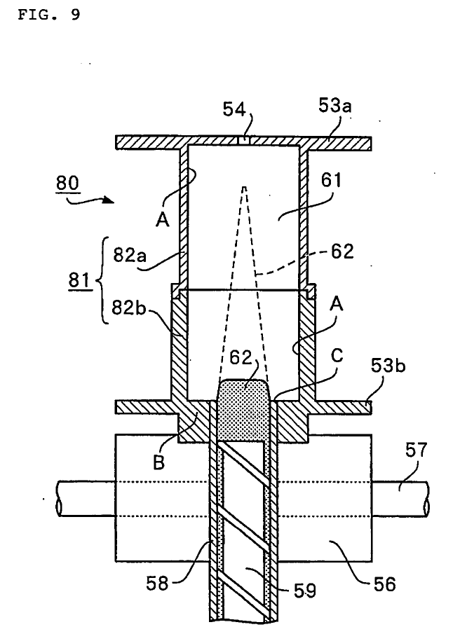

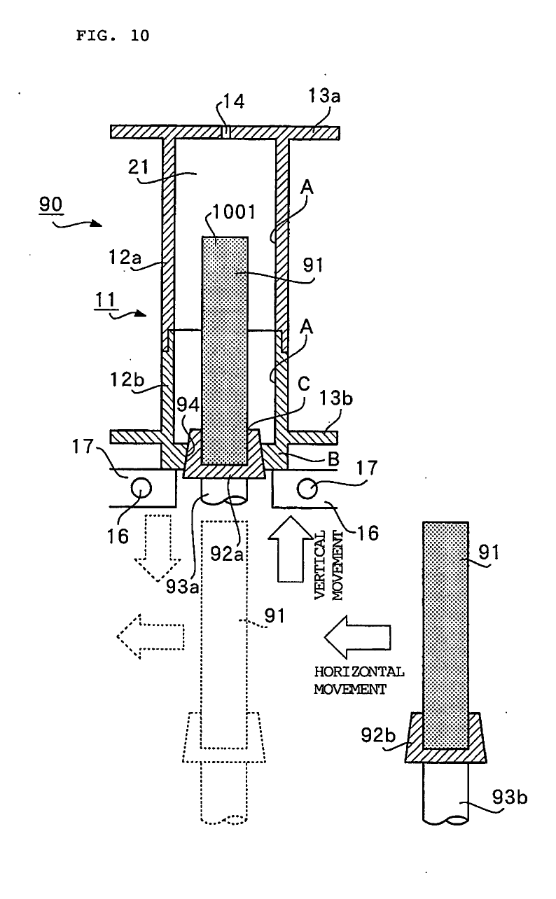

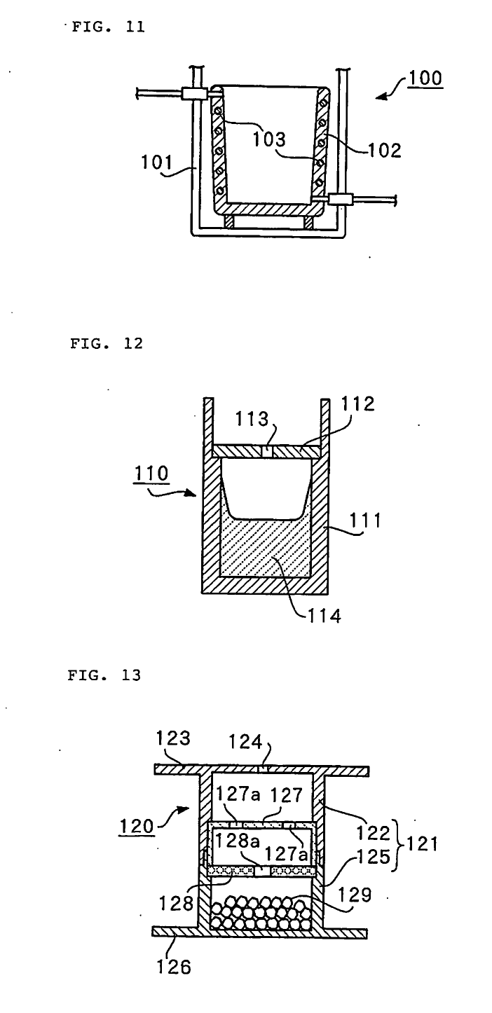

In the first embodiment, an evaporation material is, for example, a powdered grain sublimation material formed in a molded compact or in, particularly, an arbitrary shape. The first embodiment further shows an example of manually supplying a sublimation material into a heating cylinder forming a crucible as shown in FIGS. 1 and 2 and a modification thereof as shown in FIGS. 3 and 4. The second embodiment shows an example of continuously supplying an evaporation material, or sublimation material, of powdered grain particles into a tapered heating cylinder, and a modification thereof as shown in FIGS. 5, 6 and 7. The third embodiment shows an example of continuously supplying an evaporation material, or sublimation material, of powdered grain particles into a heating cylinder as shown in FIG. 8, and a modification thereof as shown in FIG. 9. In the fourth embodiment, an evaporation material is a molded compact. A heating cylinder is used. A molded compact holder is separated from the holding substrate. The evaporation material is simply supplied intermittently as shown in FIG. 10. The fourth embodiment can supply the evaporation material in a manner different from those in the second and third embodiments.

Moreover, SiO (silicon monoxide), for example, is taken up as a sublimation evaporation material in each embodiment. SiO is very broadly used for a surface protective film for an eyeglass lens, an electrical insulating film in electronic circuits, a gas shielding film for a synthetic resin film which, in this case, is converted into SiO₂ through oxidization, or the like. As the sublimation evaporation material, there are minerals such as Cr, Sn, Sr, Mg, SnO, ZnO, CdS, CdTe, PbS, and the like and organic materials such as sublimation materials of the same types.

The heating system adopted in each embodiment is a resistance heating system that generates high temperature through electrically energizing graphite, which is a material making a heating container. In the resistance heating system, the whole structure is built relatively simply. Graphite, being a constituent material, is easily available and is easily machined. The sealed-type evaporation source has an apparatus structure adapted to SiO, or an electric insulating material. However, when a conductive evaporation material is used, the apparatus structure has to be adapted to it.

### Embodiment 1

Currently, when a SiO (an evaporation material) protective film, for example, is deposited on the surface of an eyeglass lens, many lenses are arranged over the upper portion of the vacuum chamber while an open-type evaporation source is disposed on the lower portion thereof. Generally, the protective films are deposited onto the surfaces of lenses by means of the resistance heater. In this case, the deposited lenses are manually replaced with new ones. Moreover, the evaporation material is refilled manually. There are many other works for changing a substrate or an eyeglass lens being a deposition subject substrate and for refilling an evaporation material.

As SiO (or an evaporation material), there are various materials such as powdered grain particles or tables of several millimeter, precise molded materials called a target, materials of irregular sizes or shapes, and others. These evaporation materials are currently sold on market by manufactures. Other manufactures, except specific manufactures, could produce mold products from powder with a relatively simple facility.

As described above, the first embodiment corresponds to the vacuum deposition method and the sealed-type evaporation source apparatus for vacuum deposition shown in FIGS. 1 to 4. In this embodiment, replacement of a substrate and refilling of a evaporation material is performed manually.

That is, FIG. 1 is a longitudinal sectional side view conceptually illustrating the schematic configuration of a sealed-type evaporation source apparatus for vacuum deposition, according to the embodiment 1 of the present invention. FIG. 2 is a plan side view conceptually illustrating the sealed-type evaporation source apparatus for vacuum deposition, seen from above. FIG. 3 is a longitudinal sectional side view conceptually illustrating a modification of the sealed-type evaporation source apparatus for vacuum deposition. FIG. 4 is a plan view, seen from above, conceptually illustrating the sealed-type evaporation source apparatus for vacuum deposition. Referring to FIGS. 1 and 2, SiO (evaporation material) is previously formed in a molded piece. Referring to FIGS. 3 and 4, the evaporation material is in a powder state. Each evaporation material may be arbitrarily shaped, as described below.

In each of the configurations shown in FIGS. 1 and 2, a sealed-type evaporation source apparatus 10 for vacuum deposition according to the first embodiment includes a heating container 11 constituting a crucible shaped cylindrically in cross section as a whole. The heating container 11 has an upper heating cylinder 12a and a lower heating cylinder 12b, which are dividable into two and vertically. A vaporization space 21 is formed inside the heating cylinder 12a, 12b. A flange-like upper electrode 13a for resistance heating/energizing is formed on the upper end of the upper heating cylinder 12a and a flange-like lower electrode 13b for resistance heating/energizing is formed on the flange-like lower end of the lower heating cylinder 12b. The heating cylinder 12a and 12b corresponds to the active heating area A. Each of other regions corresponds to the passive heating area B. Each of the heating areas A and B increases its temperature with the heat from the heating cylinder 12a, 12b.

A blast aperture or a nozzle 14, which blasts the generated vapor, is formed in the center of the upper block section of the upper heating cylinder 12a. A recessed holder 15, which holds an evaporation material molded compact 22 to be described next, is formed in the inner bottom in the center within the lower heating cylinder 12b. The lower end of the lower heating cylinder 12b, which has the holder 15, is held and supported on the fixing stage 16. A cooling conduit 17 is built in the fixing stage 16 to cool externally the lower end of the cylinder. Thus, the corresponding portion of the heating cylinder 12a and 12b is maintained in the evaporation impossible area C or the area where the evaporation material does not evaporate by the conduction heat from the heating container 11 itself. The peripheral portion of the fixing stage 16 is protected from high temperatures.

The evaporation material, for example, SiO is previously molded in a desired shape easily held, before supplying and holding, to form the mold compact 22, although the previous molding of the powdery sublimation evaporation material SiO is not always required. For example, the evaporation material SiO may be deposited to a possible height in the recessed holder 15 shown in FIG. 1. It is preferable that the evaporation material SiO in an arbitrary shape is not in contact with the area A at an evaporation temperature. After the upper heating cylinder 12a is once divided from the lower heating cylinder 12b, the lower end of the molded compact 22 is fitted and held to the center of the holder 15. For that reason, the portion downward from the evaporation impossible area C does not reach the evaporation temperature. The molded compact 22 is maintained in a stable state.

As to the power feeder section (not shown) attached to the upper electrode 13a, the mounting structure is simplified to perform rapidly and simply the replacement of the molded compact 22 into the heating container 11. Therefore, when the molded compact 22 is replaced or refilled, the power feeder section has to be removed from the upper electrode 13a. However, because the detachment of the material sputtering prevention barrier, which is employed in the prior art, is omitted, the working is simplified and working time is shortened. In the first embodiment, it was ascertained that the molded compact 22 could be completely replaced within ten minutes.

The vaporization space 21 is between the molded compact 22 and the inner wall surface of the heating container 11, being the active heating area A. The molded compact 22 automatically vaporized from the surface thereof while a part of the generated vapor amount ejects from the blast aperture 14 having a small open area. The remaining amount of vapor is re-deposited onto the surface of the molded compact 22 and then solidified. Accordingly, there is no factor that the material is sputtered. The material sputtering phenomenon, associated with a blast of vapor, is avoided cleverly.

The molded piece 22 can be held so as to widen the surface thereof to be vaporized. That is, if evaporation occurs due to the conduction heat (corresponding to that in the prior art), the entire horizontal surface corresponding to the upper surface becomes an evaporation possible area, in district sense. However, in the embodiment 1, the entire surface, not in contact with the evaporation source, corresponds to an evaporable area, as obviously from FIG. 1. It is now assumed that the heating container is a cylindrical heater having an inner surface of 100 mm and an evaporation material held inside the heating container is evaporated by the conduction heat. The surface area is 7850 mm². For example, the evaporation material (powdered grain evaporation material SiO) in the embodiment 1 is formed in the shape of a column-shaped mold compact 22. In such a case, the diameter thereof is only 10 mm to obtain the same surface area if the height is 100 mm. This example computation means that the configuration in FIG. 1 can easily increase the evaporation possible area, even in consideration of re-solidification. In other words, the evaporation amount can be increased. That is, the above-mentioned structure can solve the problems of the sealed-type evaporation source, described in the items (1) and (2).

However, when the evaporation process continues in the aspect shown in FIG. 1, the molded compact 22 is thinned down and lowered gradually according to the evaporation amount thereof and the surface area thereof is shrunk. Necessarily, because the evaporation amount per time decreases, the current molded compact 22 has to be replaced with a new molded compact, or a new evaporation material SiO, to continue the evaporation operation. As to an improved specification, the embodiments 2 to 4 will be described below.

For reference, substantial dimensions of each constituent element in the embodiment 1 will be specifically quoted below. That is, the heating cylinder 12a and 12b of the heating cylinder 11 has an effective inner diameter of 25 mm and a height of 300 mm. The diameter of the blast aperture 14 is 1 mm and the length of the side surface thereof is 1 mm. The column-shaped molded compact 22 has an outer diameter of 12 mm and a height of 250 mm. The evaporation space 21 having an annular width of 13 mm is defined around the molded compact 22. In this aspect, the surface temperature within the heating cylinder 12a and 12b is controlled at 1400° C. By heating the molded compact 22 with the resultant radiation heat, the maximum evaporation rate becomes 30 Å/sec.

The generated vapor causes the heat disturbance motion in the evaporation space 21. Under a predetermined pressure, the vapor is sprayed from the nozzle-like blast aperture 14 toward the deposition subject substrate (not shown), where the distance to the blast aperture 14 is 600 mm, arranged inside the vacuum deposition chamber where the heating container 11 is disposed. Thus, a predetermined circular-shaped evaporation film, with the film thickness sharply increased toward the center of the substrate surface, is obtained. The molded compact 22 is gradually evaporated from the front surface thereof by the heat radiated from the inner surface of each heating cylinder 12a, 12b. Because the molded compact 21 is not in contact with other surfaces at the evaporation temperature, the molded compact 22 is in a stable state while being maintained in the vaporization space 21. As a result, the evaporation material was not sputtered at all. A thickness sensor (not shown) is disposed at a portion other than the portion immediately above the blast aperture 14.

In the sealed-type evaporation source 10 of the embodiment 1, the heating container 11 heats the molded compact 22, formed of an evaporation material SiO, in all horizontal directions of 360°. This configuration is said to be an ideal heating method. In this case, one blast aperture or blast nozzle 14 has been used but plural blast apertures can be formed. In such a heating method, plural nozzle apertures, each having a wide area, may provide a sufficient blast amount of vapor. If the evaporation material SiO does not evaporate by the conduction heat, the shape or number of the molded compact 22 should not be limited. In this case, the aperture shape, aperture area, and number of the blast aperture 14 cannot be specified but is determined by the relative relationship between vapor amount and pressure in the heating container 11. However, those factors are arbitrary if the pressure in the heating container 11 promotes re-solidification of vapor to be required. Powdered grains of evaporation materials SiO can be piled onto the holder 15. If the evaporation material is not a sublimation property, its molded compact cannot be maintained in shape due to liquefaction. As a result, the evaporation material may be subjected to the conduction heat in contact with the heating container 11.

Now, the position of the blast aperture or blast nozzle 14 is not specified. However, the aperture formed area corresponds to the passive heating area B previously described, which may be set to less than the evaporation temperature. In such a case, because the solidified vapor may block the blast aperture 14, the temperature that maintains an open state has to be set.

In the first embodiment, the heating container 11 is mounted in a vertical state. However, the molded evaporation material SiO can be held horizontally or slantingly through an ingenious design, for example, by supporting the material on both ends thereof.

A modification of the first embodiment shown in FIG. 1 and 2 will be explained below by referring to FIGS. 3 and 4. In the first embodiment uses the molded compact 22 formed of an evaporation material SiO. However, the modification uses the evaporation material SiO as powder particles 23. The powder particles 23 are replenished manually.

In the configuration of FIGS. 3 and 4, the sealed-type evaporation source apparatus 30 being a modification of the first embodiment has a heating container 31 building a nearly rectangular crucible. The heating container 31 is formed of a holder case 32 that detachably blocks the rectangular cylinder receiving powdered evaporation materials SiO powdered particles 23 and the lower end thereof and a heating plate 33 that blocks detachably the upper end of the holder case 32. The vaporization space 41 is formed inside the holder cylinder 32. A set of the upper electrode 33a and the lower electrode 33b, formed to the heating plate 33, defines the active heating area A. A blast aperture or nozzle 34 is formed in the center of the heating plate 33 to emit the generated vapor.

The lower end of the holder case 23 is fixed and supported on the fixing stage or base 36 so that a holder is formed for the powder particles 23. The cooling conduit 37 buried in the fixing stage 36 cools externally the lower end of the holder case 32. Thus, the corresponding portions of each of the holder case 32 and the fixing base 36 are maintained to the evaporation impossible area C. The cooling conduit 37 prevents the peripheral portion of the fixing base 36 from the high heat. As a result, the inner surface of the holder case 32 acts as the passive heating area B. Like the first embodiment, the mounting structure of the power feeder (not shown) attached to each electrode 33a and 33b of the heating plate 32 is simplified as degree as possible to facilitate refilling the powder particles 23 quickly and simply to the inside of the holder cylinder 32.

In the structure of the modification, the power feeder is removed from the electrode 33a and 33b. Then, the heating plate 33 is once opened and the powder particles 23 are refilled into the inside of the holder structure 32 while being leveled. As apparent from FIG. 3, the height or thickness of the powder particles 23 is matched to the height of the upper fringe of the upper fringe of the fixing stage 36, or to the upper limit of the vaporization impossible area C by conduction heat. Thereafter, the heating plate 33 is set to the original shut state. The power feeder corresponding to the electrode 33a and the power feeder corresponding to the electrode 33b are attached to the heating plate 33 and supplies electric power. Thus, the heating plate 33 is subjected to the resistance heating. Even in the modification, it has been ascertained that the powder particles 23 are completely refilled within ten minutes.

For reference, the substantial dimensions of each constituent element in the modification of the first embodiment are cited specifically. That is, the dimension of the inner surface of the fixing stage 36 (or the bottom surface of the holding case 32), or the inner dimension of the holder for the powder particles 23, is 100 mm ×90 mm. The powder particles 23 are bedded and held in a thickness of 3 mm. In this case, the blast aperture 34 has a diameter of 1 mm and the side surface thereof is 1 mm. The distance between the inner surface of the heating plate 33 defining the vaporization space 41 and the upper surface of the powder particles 23 held and paved is 12 mm. In this aspect, the heating plate 33 is controlled to the surface temperature of 1400° C. and the radiation heat heats the powder articles 23. Thus, like the first embodiment, a maximum evaporation rate of 30 Å/sec was obtained.

In this case, the generated vapor heat causes the heat disturbance motion inside the vaporization space 41. Under a predetermined pressure, the vapor is emitted from the nozzle-like blast aperture 34 onto the surface of the evaporation subject substrate (not shown) at the distance of 600 mm from the blast aperture 34. A circular predetermined deposited film is sharply thickened toward the center of the substrate surface. The powder particles 23 are contained inside the vaporization space 41 and are in a stable state because being not in contact with the surface at other evaporation temperature. As a result, the material sputtering does not occur at all. In this case, the thickness sensor (not shown) is placed at an area, except the area immediately above the blast aperture 34.

### Embodiment 2

The second embodiment relates to the vacuum deposition method and the sealed-type evaporation source apparatus corresponding to the vacuum deposition method as shown in FIGS. 5-9. This embodiment can be applied practically to the case where the long lengths of a gas barrier film are continuously produced. Thus, SiO, for example, is deposited by supplying oxygen while SiO is being emitted onto a synthetic resin film, such as polyester film.

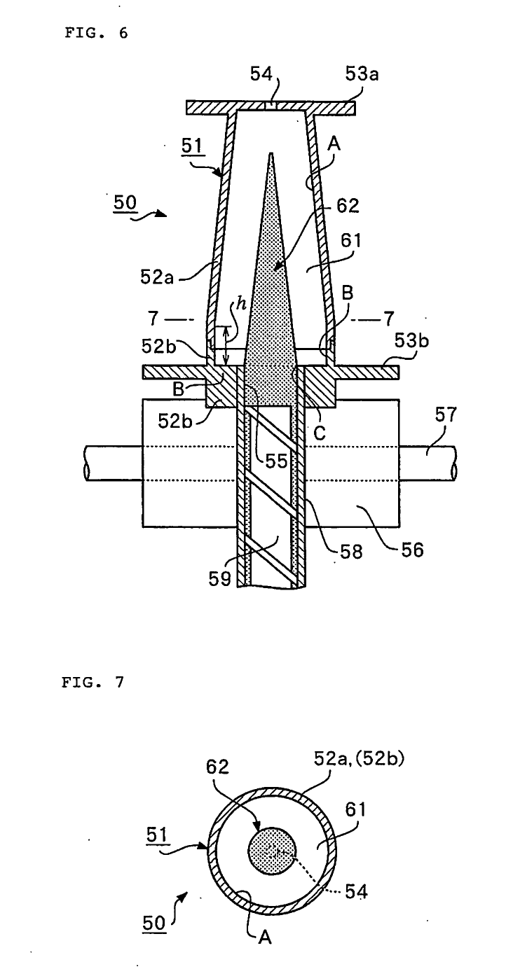

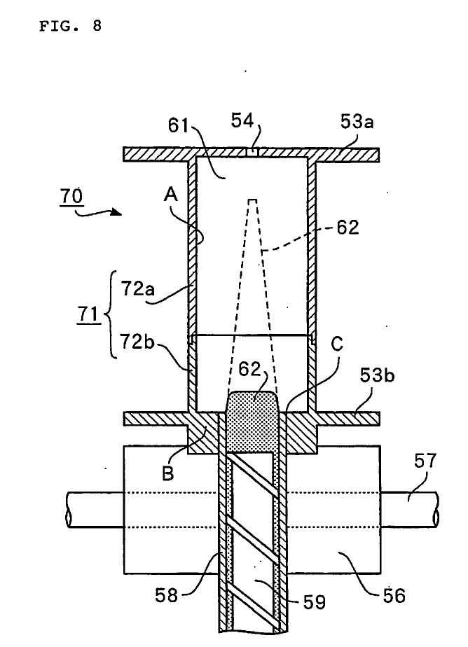

FIG. 5 is a longitudinal, sectional side view conceptually illustrating the schematic configuration of a sealed-type evaporation source apparatus for vacuum deposition, according to the second embodiment of the present invention. FIG. 6 is a longitudinal, sectional side view conceptually illustrating the aspect after a lapse of a certain time of the operation of the sealed-type evaporation source apparatus in FIG. 5. FIG. 7 is a cross-sectional view schematically illustrating the portion taken along the line 7-7 in FIG. 6.

In each configuration of FIGS. 5 to 7, the sealed-type evaporation source apparatus 50 for vacuum deposition according to the second embodiment includes a heating container 51 formed of an upper heating cylinder 52a and a lower heating cylinder 52b, which form a crucible. The upper heating cylinder 52a is tapered down gradually toward the upper portion from the portion of the height h. The lower heating cylinder 52b is the straight portion that can be detachably combined with the lower end of the upper heating cylinder 52b. The vaporization space 61 is formed in each heating cylinder 52a and 52b.

A flange-like upper electrode 53a for conduction in resistance heating is formed to the upper end of the upper heating cylinder 52a and a flange-like lower electrode 53b for conduction in resistance heating is formed to the lower end of the lower heating cylinder 52b. In this case, the tapered upper heating cylinder 52a increases its electric resistance value, with the region positioned upward, so that the temperature rises. The heating cylinder 52a energized by the electrode 53a and the heating cylinder 52b energized by the electrode 53b correspond to the active heating area A. The other region corresponds to a passive heating area B. The temperature of the active heating area A increases by the heat from the heating cylinder 52a and 52b.

The blast aperture or nozzle 54 is formed in the center of the upper dead end of the upper heating cylinder 52a. That is, an evaporation material supply opening is formed in the center of the lower end in the lower heating cylinder 52b. An evaporation material supply tube 58 for supplying an evaporation material, for example, SiO, and forming and holding a growth body 62 and a feeding screw 59 for rotatably feeding the evaporation material into the feeder tube 58 are attached to the supply opening. In a manner nearly similar to that in the first embodiment, the lower end of the lower heating cylinder 12b is fixed on the fixing stage 56. A cooling conduit 57 is built in the fixing stage 56 to forcedly cool the cylinder lower end externally. Thus, the evaporation material feeder conduit 58 and the feeding screw 59, which include the heating cylinder 12, is maintained as the evaporation impossible area C.

In the configuration of the embodiment 2, the heating container 51 is heated up to a vaporable temperature while no powdered evaporation material SiO exists in the vaporization space 61. Referring to FIG. 5, the powdered evaporation material SiO is somewhat raised upward toward the vaporization space 61. However, the existence of the raised portion is not necessarily required at the beginning of heating. The corresponding operation is performed when the status of FIG. 5 is changed to the status of FIG. 6.

In other words, when the heating container 51 reaches the vaporization temperature, the feeding screw 59 starts the rotational driving. The feeding screw 59 pushes up gradually toward the vaporable area through the evaporation material supply tube 58 corresponding to the holder 15 in the first embodiment. In the state of FIG. 5, the upper portion of the raised evaporation material SiO is subjected to the vaporization space 61 pressurized due to heating. The evaporation material SiO begins the vaporization by the radiation heat from the inner surface of the heating container 51, or the active heating area A. As to the vapor thus generated, part thereof is emitted out from the blast aperture 54 under high pressure in the vaporization space 61, as described in the first embodiment. The remainder re-solidifies onto the surface of the evaporation material SiO, which is pushed up, and then solidifies. This order continues.

The vapor re-solidification phenomenon onto the surface of the evaporation material SiO is peculiar to the sealed-type evaporation source, but is not seen or is very rare in the open-type evaporation source. The vapor re-solidification means that the outer film, having a certain hardness and strength, is created on the surface of the evaporation material SiO being pushed up. The powder compact of an evaporation material SiO, continuously pushed up, does not totally collapsed due to the hard outer cover. Moreover, since the re-solidification is made immediately and continuously, the evaporation material continuously grows in column state as a predetermined grown body 62, as shown with the broken lines in FIG. 5 and with the solid lines in FIG. 6.

In order to push up and feed smoothly the powdered evaporation material SiO through the evaporation material supply tube 58 by means of the feeding screw 59, the powder compact, which directly undergoes the feeding force, has to be move freely. Hence, the heat conducted to the evaporation supply tube 58 has to be controlled below the temperature at which the passing evaporation material SiO evaporates.

That is, if the evaporation material SiO vaporizes due to the conduction heat in the feeding process, the vapor re-solidifies instantaneously on the adjacent areas, and it disrupts the free movement of the evaporation material SiO. Therefore, the area C, where vaporization is impossible, is required to avoid such re-solidification.

In the feeding process, the surface area of the evaporation material SiO gradually increases during the continuous column growth and the evaporation amount increases. When the growth body 62 reaches a height, the growth amount or the feeding amount of the evaporation material SiO equilibrates with the vapor-jet amount from the blast aperture. Therefore, the growth body 62 is shaped in a nearly cone form having a predetermined height, while maintaining in a predetermined shape. Thus, a nearly constant evaporation amount is continuously generated. In this aspect, the sputtering of the material does not occur. In this state, under the constant temperature in the crucible, the total amount of three factors per time, namely, the vapor amount of the jet flow, plus the vapor amount in the crucible and plus the vapor amount of re-solidification, is equal to the amount of vaporization per time. Accordingly the equilibrium vapor pressure exists in the crucible. That is, the constant vapor jet is obtained. Thus, a long time stable vacuum deposition becomes possible by the sealed-type evaporation source apparatus.

The above-mentioned principles means that the re-solidification in the item (2) describing the problem of the sealed-type evaporation source is effectively used. Moreover, even if the re-solidification causes a decrease of the evaporation amount per area from the growth body 62, the evaporation surface area can be made large by growing the evaporation material SiO in a column form. Thus, the decreased amount can be compensated fully. Since it is not required to consider the sputtering of the evaporation material, the heating temperature can be increased. As a result, the evaporation amount more than that by the open-type evaporation source can be obtained.

In the specification of each constituent element of the sealed-type evaporation source in the second embodiment, the inner diameter of the lower end of the upper heating cylinder 52a is 25 mm and the inner diameter of the lower end of the lower heating cylinder 52b is 25 mm. The inner diameter of the blast aperture 54 of the upper heating cylinder 52a is 20 mm. The height of the complete heating container 51 is 350 mm. The evaporation material feeding tube 58 and the feeding screw 59 are made of molybdenum. The inner diameter of the evaporation material supply tube 28 is 11 mm. The crest diameter of the feeding screw 59 is 10.5 mm. The nozzle diameter of the blast aperture 54 is 1 mm and the length of the side wall thereof is 1 mm. Thus, the ambient temperature can be controlled at 1400° C. and the temperature of the area C, where vaporization is impossible, can be controlled at 1200° C. As to the deposition operation in that state, the vapor blast amount increased for 20 minutes after beginning the supply of the evaporation material SiO but then was settled to a fixed evaporation value. In this case, the evaporation rate was 30 Å/sec.

### Embodiment 3

The third embodiment corresponds to a variation of the heating the container in the second embodiment.

FIG. 8 is a longitudinal sectional side view conceptually illustrating the schematic configuration of a sealed-type evaporation source apparatus for vacuum deposition according to the third embodiment. FIG. 9 is a longitudinal sectional view conceptually illustrating a modification of the sealed-type evaporation source apparatus.

In the sealed-type evaporation source apparatus 70 shown in FIG. 8, the heating container 71 has a straight cylinder, different from the tapered container shown in the second embodiment. The heating container 71 are formed of an upper heating cylinder 72a and a lower heating cylinder 72b, which are vertically dividable. Other constituent elements are identical to those in the embodiment 2. In this case, like numerals are attached to the common constituent elements shown in FIGS. 8 and 9.

In the sealed type evaporation source of the third embodiment, the dimensions basically are substantially identical to those in the second embodiment. However, the upper heating cylinder 72a and the outer heating cylinder 72b constituting the heating container 71 have an inner diameter of 25 mm and are in a straight form. The evaporation conditions and the evaporation results are generally identical to those in the second embodiment.

Next, the reason for the modified cylinder of the heating container 71 will be described. In the tapered heating container 5 in the second embodiment, the upper heating cylinder 52a is gradually tapered toward the upper portion so that the electrical resistance value increases gradually. This approach is reasonable. That is, the area C where disables the evaporation due to the conduction heat at the corresponding portion of the upper heating cylinder 52a is maintained at a low temperature. The evaporation amount adjacent to the blast aperture 54 can be effectively increased. However, in an actual case, even if the whole of the heating container 51 is at an even temperature, the column-like growth body 62 are grown in the form of a nearly cone having an apex near the blast aperture 54. Accordingly, when the vapor within the vaporization space 61 in a heat disturbance motion state, the valor adjacent to the blast aperture 54 tends to be easily emitted.

In the third embodiment shown in FIG. 8, the sealed-type evaporation source apparatus 70 has a straight heating container 71. The heating container 71 can be divided into an upper heating cylinder 72a and a lower heating cylinder 72b. This is chiefly required for the process necessity and convenient operation. Each cylinder has a fixed thickness. In this case, the area at least adjacent to the blast aperture 74 in the heating container 71 has to be at an evaporation temperature. However, because the active heating area A between the upper electrode and the lower electrode has the same electric resistance value, when the upper portion is, for example, at 1400° C., the lower portion becomes 1400° C. In such a state, the growth body of the evaporation material SiO is exposed to a high temperature radiation heat so that the evaporation amount increases. Moreover, the vapor blast amount from the blast aperture 74 also increases in proportion to the increased evaporation amount. The feeding amount of the evaporation material SiO can be increased by the increased vapor blast amount.

However, the conduction heat, to be normally maintained at a relatively low temperature, may increase the temperature of the vaporizationless area C. The vaporizationless area C has to be forcedly cooled because this may often reach the evaporation temperature. For that reason, in the normal case, the temperature of the cooling water flowing through the cooling conduit is lowered or the flow amount thereof is increased. This can suppress an excessive increase in temperature of the vaporizationless area C.

In the modification in the third embodiment shown in FIG. 9, the heating container 81 of the sealed-type evaporation source apparatus 80 is built of an upper heating cylinder 82a and a lower heating cylinder 82b, which are dividable from each other. The wall thickness of the upper heating cylinder 82 is thinner than that of the lower heating cylinder 82b. In this case, because the electric resistance value of the lower heating cylinder 82a is smaller than that of the lower heating cylinder 82b, the electric resistance value of the active heating area A of the lower heating cylinder 82b is lower than that of the upper heating cylinder 82a.

That is, in the configuration shown in FIG. 9, the upper portion adjacent to the blast aperture 54 is at a high temperature, the lower portion can be maintained at a low temperature at which the evaporation does not occur due to the conduction heat. However, because the radiation heat affects all over the vaporization space, there is not a large difference in the evaporation efficiency.

In the apparatus configuration, the straight cylinder can be designed and fabricated more easily than the tapered container and the configuration of FIG. 8 is preferable for temperature control. The temperature of the cylinder drops through the heat dissipation during the continuous evaporation, as previously described. One approach is to adopt the configuration that can previously set a necessary portion at a high temperature, for example, to form the heating container in the shape as shown in FIGS. 5 and 9. In another approach, the entire height of the apparatus is formed so as to raise somewhat for example, in the shape as shown in FIG. 8.

### Embodiment 4

The fourth embodiment relates to the vacuum deposition method and the sealed-type evaporation source apparatus for vacuum deposition as shown in FIG. 10.

FIG. 10 is a longitudinal sectional side view conceptually illustrating the configuration of the sealed-type evaporation source apparatus for deposition according to the fourth embodiment of the present invention. In the fourth embodiment, the operation of replacing and feeding the molded compact 22 of the evaporation material SiO, in the first embodiment can performed in a simple intermittent operation. Like numerals are attached to the same elements as those in the first embodiment. Only the related elements will be explained below.

In the fourth embodiment, the dimensions of the heating container and the evaporation conditions fundamentally are substantially the same as those in the first embodiment, thus leading to the same evaporation results.

In the sealed-type evaporation source apparatus for vacuum deposition according to the fourth embodiment shown in FIG. 10, the molded compact 91 of the evaporation material SiO corresponding to the growth compact 22 in the first embodiment and a pair of holders 92a and 92b corresponding to the holder 15 in the first embodiment, each of which holds the base end of the molded compact 91, are mounted separably from the apparatus. A manipulation stick 93a for replacement operation is attached to the lower end of the holder 92a and a manipulation stick 93b for replacement operation is attached to the lower end of the holder 92b. In the fourth embodiment, the evaporation material SiO is restrictedly used as only the molded compact 91 molded and prepared in a predetermined shape but is not used in a powdered state. Moreover, in the fourth embodiment, the heating container corresponding to the heating container 11 in the first embodiment is separable vertically into two cylinders corresponding to the upper heating cylinder 12a and the lower heating cylinder 12b in the first embodiment. This is merely implemented because of the necessity of processing, not to replenish the evaporation material SiO as in the first embodiment.

The operation of the fourth embodiment will be described specifically here. The holder 92a and 92b previously holds the molded compact 91. In the set-up stage for a deposition work, the holder 92a, for example, is set inside the heating cylinder to hold a portion of the molded compact 91 protruded from the lower mounting hole 94 of the apparatus body, as shown in FIG. 10. In order to certainly perform the quick mounting, the outer surface of the holder 92a and 92b is somewhat tapered and is slidably contacted with the inner surface of the lower mounting hole 94. In addition, when the operation stick 93a and 93b is temporarily mounted to the structure in the mounting state, the holder 92a and 92b, which holds the molded compact 91, is prevented from dropping. Moreover, the conduction heat can be dissipated more.

With the molded compact 91 thus attached, the desired heating and deposition is continuously carried out after loading the deposition subject substrate and evacuating the chamber, in a manner similar to that in the first embodiment.

As described and shown in detail with FIG. 10, the completely used holder 92a was able to be simply replaced with a new holder 92b, in this case, in about two minutes. The replacement work is manually performed sufficiently. However, if necessary, plural molded compact holders, for example, may be used. Thus, the molded compact may be automatically replaced. For example, the conveyor, which intermittently rotates horizontally, conveys each holder to the mounting position under the heating container and then moves it vertically.

### INDUSTRIAL APPLICABILITY

In the sealed-type evaporation sources shown in the first to fourth embodiments, a cylindrical heating container is used, except that those shown in FIGS. 3 and 4 according to the first embodiment. The circular form in horizontal section allows the radiation heat from all directions of 360° to be radiated uniformly. It is most desirable that the molded compact or growth body of an evaporation material heated and evaporated due to the radiation heat has a circular cross-section. Thus, the evaporation amount becomes relatively large. The heating container and the molded compact or growth body of an evaporation material may have a different cross-section. Similarly, it is most suitable that a molded compact or growth body of an evaporation material is held or fed at the center in horizontal cross-section in the heating container. The evaporation material may be held or fed at a different position.

A tapered heating container is shown in FIGS. 5 and 6 related to the second embodiment. A straight heating container is shown in FIGS. 8 and 9 related in the third embodiment. Referring to FIG. 9, the lower portion of the cylinder has a large thickness. Thus, the heating cylinders are made differently in such a way that the temperature distribution over which an evaporation material is heated and evaporated is suitable for the evaporation. That is, in the case of FIGS. 5 and 6, the heating cylinder is tapered such that the heating temperature in the lower inner surface is lower than the heating temperature of the upper inner surface. In the case of FIG. 8, the heating temperature is equalized all over the inner surface. In the case of FIG. 9, the side having a larger wall thickness is maintained to a low heating temperature.

In either case, the basic requirement is that the heating container or cylinder must have the evaporationless area C defined at an applicable portion. Further basic requirement is to spur the evaporation of the evaporation material and to easily guide the flow of the generated vapor toward the blast aperture. The above mentioned circular configuration can satisfy the above mentioned requirements. In the other case, it is preferable, for example, that the heating temperature is controllably suppressed to a minimum limit sufficient for evaporation of an evaporation material and the volume of the necessary area is made large to have a margin of the heat energy amount.

As to the configuration of the second embodiment, the process of pushing up an evaporation material from the upper end of the evaporation material supply tube into the vaporization space and then growing the vapor into a growth body has been explained in detail. However, further explanation is added. That is, when powder particles of an evaporation material, for example, are compressed under a certain condition or any condition preventing other free motion exits, a set of powder particles has a kind of moldability under the influence. However, over the influenced range, the set of powder particles has a very unstable moldability and lacks the reproducibility and the time consistency. When the surface of the growth body solidifies through the re-solidification of vapor and thus grows, the reproducibility and the time consistency are satisfied, so that the growth is effectively realized. In other words, evaporation from the surface of a growth body, re-solidification of a certain amount of vapor onto the growth body surface (the vapor not re-solidified is emitted from the blast aperture), re-evaporation of vapor on the surface, and re-solidification of a certain amount of vapor onto the growth body surface are repeated during heating and evaporation of the evaporation material. In these phenomena, the growth body grows due to the existence of a vapor pressure in the sealed-type evaporation source, that is, due to the existence of heat disturbance motion and due to the temperature of an evaporation material which does-not indicate a sensible heat in principle by the radiation heat on the vapor side. The growth into the column state accompanied by each phenomenon is possible in only the sealed-type evaporation source.

FIGS. 12 and 13 show the system for realizing a sealed state with only the elements constituting a heating container. However, when an evaporation material is evaporated with the radiation heat, the evaporation material itself can maintain its sealing property because the evaporation material is not in motion inside the heating container. That is, referring to the second embodiment shown in FIG. 5, because very minute spaces exit between powder particles of an evaporation material, a set of powder particles can sufficiently block gases in practical use. Re-solidification of vapor onto the surface of a growth body means that the spaces between powder particles at the space interface are filled in. This realizes the sealing property. Moreover, when the evaporation material is a molded compact, the spaces are sufficiently sealed by the system according to the fourth embodiment shown in FIG. 10. However, even if the fixing base is in direct contact with the molded compact, the evaporation due to the conduction heat does not occur in the area. Hence, the spaces are blocked through the re-solidification of vapor, regardless of the presence or absence of some space or gap.

Generally, in the sealed-type evaporation source, the system is built with an assembly of some components. In other words, an assembly of components results in spaces existing in the interfaces between components. In the fourth embodiment shown in FIG. 10, the holder for holding a molded compact of an evaporation material is slidably fit and detachably connected to the lower mounting hole in the fixing base on the bottom of the heating container. Referring to FIG. 10, the holder is closely connected to the bottom of the heating container in a tapered fitting mode. However, it is preferable that the fitting state is relatively loose to perform the detachable operation or there is some space or gap between the two members. Such a space may deteriorate the sealing performance. Because the conduction heat maintains the peripheral portion to an evaporation impossible temperature, the generated vapor immediately travels into the space with the heat disturbance motion, so that the space is filled with the re-solidification. That is, the sealing property is effectively maintained.

Even if the same amount of heat energy, for example, a fixed amount of electric energy, is supplied, the heat temperature of the heating container falls as the evaporation material grows tall in a column form. This results from the fact that the evaporation material absorbs the heat of the heating container. As a result, because both the evaporation amount and the blast amount reduce, the temperature of the heating container has to be compensated by the reduced amount. For the temperature compensation, a temperature detector such as a thermocouple is disposed to the heating container to measure the reduced temperature. By doing so, energy is more supplied for temperature compensation. For example, the supply current is increased in the resistance heating system.

As described above, since the evaporation material continuously supplied in a powder state enables the deposition operation for a long time. In this system, since the evaporation surfaces of a relatively small amount of evaporation materials are merely heated with the radiation heat, the necessary heat energy becomes remarkably small. As a result, the apparatus that saves energy can be built. These sealed-type evaporation source apparatuses according to the present invention do not exsist.

Obviously, many modifications and variations of the present invention are possible in the light of the above teachings. It is therefore to be understood that within the scope of the appended claims, the invention may be practiced otherwise than as specifically described.

1. A vacuum deposition method for evaporating a sublimation evaporation material, comprising the steps of:
preparing a gas sealed-type heating container having a blast aperture;
holding said evaporation material in an area where said evaporation material does not evaporate due to heat conduction from said gas sealed heating container;
evaporating said evaporation material held in said area by radiation heat from said heating container; and
emitting the resultant vapor from said aperture toward a deposition subject surface outside said heating container.

2. The vacuum deposition method as defined in claim 1, wherein said heating container has a supply aperture in an area where said evaporation material does not evaporate due to the heat conducted from said heating container; wherein said evaporation material supplied from said supply aperture is held in the area where said evaporation material does not evaporate due to the heat conducted from said heating container; and wherein said evaporation material to be supplied and held is held in an evaporation area subjected to said radiation heat, so as to face in a contact-less state a heating surface at an evaporable temperature within said heating container.

3. The vacuum deposition method as defined in claim 2, wherein said evaporation material is in a powdered grain state and is supplied from a supply aperture formed in said heating container; and wherein said evaporation material to be supplied is held in an evaporation area subjected to said radiation heat, so as to confront in a contactless state said heating surface at an evaporable temperature within said heating container.

4. The vacuum deposition method as defined in claim 3, wherein vapor of said evaporation material produced due to a radiation heat from a heating surface of said heating container performs a thermal disturbance motion in a space within said heating container while part of said vapor is re-solidified onto the surface of said evaporation material, thus being maintained to a solid phase in a predetermined state.

5. The vacuum deposition method as defined in claim 2, wherein said evaporation material is a molded compact and is supplied from a supply aperture formed in said heating container; and wherein an evaporation material to be supplied is held in an evaporation area subjected to said radiation heat so as to confront in a contact-less state said heating surface in said heating container, which is at an evaporable temperature.

6. The vacuum deposition method as defined in claim 3, wherein the gas sealing property of said supply aperture formed in said heat container is maintained by said powdered grain evaporation material or said molded compact evaporation material, supplied via said supply aperture.

7. The vacuum deposition method as defined in claim 2, wherein the gas sealing property of said supply aperture formed in said heat container is maintained by a solid state phase of said vapor partially re-solidified.

8. The vacuum deposition method as defined in claim 3, wherein said powdered grain evaporation material is supplied to said supply aperture as said emission of said evaporation material reduces in said heating container.

9. A sealed-type evaporation source apparatus for vacuum deposition of a sublimation evaporation material comprising:
a gas sealed heating container having a blast aperture and having an area vaporizing said evaporation material with a radiation heat from an inner surface thereof; and
a holder for holding said evaporation material in an area where said evaporation material does not evaporate with a conduction heat from said heating container;
whereby said blast aperture emits the generated vapor toward an evaporation subject surface outside said container.

10. The sealed-type evaporation source apparatus for vacuum deposition as defined in claim 9, wherein said heating container has a supply aperture for evaporation material in an area where said evaporation material does not evaporate by a conduction heat from said heating container; wherein said evaporation material to be supplied from said supply aperture is held in an area where said evaporation material does not evaporate by a conduction heat from said heating container; and wherein said evaporation material to be supplied and held is held in an evaporation area subjected to said radiation heat, so as to confront in a contactless state a heating surface at an evaporable temperature in said heating container.

11. The sealed-type evaporation source apparatus for vacuum deposition as defined in claim 10, wherein said evaporation material is in a powdered grain state and is supplied from a supply aperture formed in said heating container; and wherein said evaporation material to be supplied is held in an area subject to said radioactive heat, so as to confront in a contactless state said heating surface at an evaporable temperature in said heating container.

12. The sealed-type evaporation source apparatus for vacuum deposition as defined in claim 10, wherein said evaporation material is a molded compact and is supplied from a supply aperture formed in said heating container; and wherein said evaporation material is held in an evaporation area subject to said radiation heat so as to confront in contactless state said heating surface of said heating container, which is at an evaporable temperature.

13. The sealed-type evaporation source apparatus for vacuum deposition as defined in claim 9, wherein said evaporation material supply aperture and said holder are disposed in the position where said evaporation material does not evaporate due to a conduction heat from said heating container.

14. The sealed-type evaporation source apparatus for vacuum deposition as defined in claim 10, wherein the gas sealing property of said supply aperture formed in said heat container is maintained due to said powdered gain evaporation material or said molded compact evaporation material, supplied via said supply aperture.

15. The sealed-type evaporation source apparatus for vacuum deposition as defined in claim 10, wherein the gas sealing property of said supply aperture formed in said heat container is maintained by a solid state phase of said vapor partially re-deposited.

16. The sealed-type evaporation source for vacuum deposition as defined in claim 11, wherein said powdered grain evaporation material is supplied to said supply aperture as the emission of said evaporation material reduces in said heating container.
